(19) United States
(12) Patent Application Publication
(10) Pub. No.: US 2026/0003009 A1
(43) Pub. Date: Jan. 1, 2026

(54) BIDIRECTIONAL POWER CONVERSION TOPOLOGY FOR POWER BATTERY TEST EXCITATION POWER SUPPLY, METHOD AND SYSTEM

(71) Applicant: SHANDONG UNIVERSITY, Jinan (CN)

(72) Inventors: Chenghui ZHANG, Jinan (CN); Wenlong DING, Jinan (CN); Bin DUAN, Jinan (CN); Chenzhong ZHANG, Jinan (CN); Jinqiu SONG, Jinan (CN)

(21) Appl. No.: 19/110,126

(22) PCT Filed: Oct. 17, 2022
(86) PCT No.: PCT/CN2022/125721

§ 371 Date: May 9, 2025

(30) Foreign Application Priority Data
Sep. 9, 2022 (CN) 202211102328.5

(51) Int. Cl. G01R 31/396; G01R 31/382; H02J 7/00; H02J 7/06; H02M 1/00; H02M 7/797

(52) U.S. Cl. CPC G01R 31/396; G01R 31/382; H02J 7/0063; H02J 7/06; H02M 1/007; H02M 7/797

(57) ABSTRACT

The present invention provides a topology, method and system for bi-directional power conversion of excitation power supply for power battery testing, wherein the topology comprises a three-phase PWM (pulse width modulation) converter, a high-frequency isolation three-level LLC (logical link control) resonant converter and a DC-DC (direct current) converter forming a topology structure for a three-stage power conversion; an input end of the three-phase PWM converter is connected to a power grid side; the high-frequency isolation three-level LLC resonant converter is connected between the three-phase PWM converter and the DC-DC converter in series and is configured for realizing bi-directional DC voltage conversion and isolation, and to raise a busbar voltage between the high-frequency isolation three-level LLC resonant converter and the DC-DC converter; and, the DC-DC converter is configured to generate charging and discharging excitation currents for a power battery testing.

The present invention claims priority benefits to Chinese Patent Application number of 202211102328.5, entitled “A Topology, Method and System for Bi-directional Power Conversion of Excitation Power Supply for Power Battery Testing”, filed on Sep. 9, 2022, with the China National Intellectual Property Administration (CNIPA), the entire contents of which are incorporated herein by reference.

### TECHNICAL FIELD

The present invention belongs to the technical field of testing systems for power batteries or energy storage batteries, and particularly relates to a topology, method and system for bi-directional power conversion of excitation power supply for power battery testing.

### BACKGROUND

The statements in this section merely provide background information related to the present invention and do not necessarily constitute prior art.

Power batteries are the core component of new energy storage systems and electric vehicles, and the performance thereof directly affects the system performance. A power battery characteristic testing is of irreplaceable significance for battery research and development, production manufacturing and application management. Especially with the rapid development of new energy storage system and long-term driving range of electric vehicles, the trend of large capacity and high voltage of power battery pack is becoming more and more obvious, and it is urgent to develop a measurement and control system or test instrument with wide output voltage range, fast response and high efficiency for the high-power batteries.

The measurement and control system for power battery is composed of an excitation power supply, a software platform, a data synchronous acquisition and other subsystems, in which the excitation power supply is the core device that outputs charging and discharging excitation currents that directly acts on batteries, and is basically required to have fast charging and discharging conversion speed for high current, no overshoot, low ripple, high efficiency, high power density and so on. At present, the international general solution is composed of a power frequency isolation transformer, an alternating current (AC)-direct current (DC) converter and a DC-DC converter; in this topology structure, the bulky power frequency isolation transformer needs to be connected in front of the AC-DC converter for boosting, which not only makes the whole system has a large volume, low power density, and high loss, but also has a low switching frequency, slow charge-discharge conversion speed, poor test accuracy because of using traditional silicon-based devices, and the system further has a large overshoot ripple, causing damage to the batteries. In view of the above problems, a new solution using silicon carbide power switching devices and high-frequency isolation transformers is proposed to greatly improve the switching frequency. And, a three-stage power conversion topology composed of a three-phase pulse width modulation (PWM) converter+high-frequency isolation DC-DC converter+DC-DC converter is formed through replacing the power frequency isolation transformer with a high-frequency isolation transformer, which effectively improves the accuracy of battery testing and realizes the innovation of traditional solutions and the upgrading of instruments.

In a category of the high-frequency isolation DC-DC converter, a logical link control (LLC) resonant converter has advantages such as natural soft switching characteristics in wide input or output voltage range, which is suitable for the measurement and control system for battery. However, a topology structure of a secondary side of the LLC resonant converter usually is a full-bridge circuit or a voltage doubler circuit and the like, can no longer meet the requirements of the continuous improvement of battery voltage level and power level, and has a poor applicability in high-voltage and high-power applications. The present inventor(s) found that although the solution of using devices in series can reduce voltage stress, but it will bring about voltage equalization problems; the solution of using converters in series will increase losses and costs.

### SUMMARY

To solve the technical problems existing in the above prior arts, the present invention provides a topology, method and system for bi-directional power conversion of excitation power supply for power battery testing, using a bi-directional three-level LLC resonant converter to reduce voltage stress of switch transistor; simultaneously, high-frequency isolation DC-DC converter is configured to be in a multi-channel parallel connection form to achieve a flexible control of system power.

In order to achieve the above objects, the present invention adopts the following technical solutions.

A first aspect of the invention provides a topology for bi-directional power conversion of an excitation power supply for power battery testing, comprising:
a three-phase PWM converter, a high-frequency isolation three-level LLC resonant converter and a DC-DC converter forming a topology structure for a three-stage power conversion; wherein,
an input end of the three-phase PWM converter is connected to a power grid side; the high-frequency isolation three-level LLC resonant converter is connected between the three-phase PWM converter and the DC-DC converter in series and is configured for realizing bi-directional DC voltage conversion and isolation, and to raise a busbar voltage between the high-frequency isolation three-level LLC resonant converter and the DC-DC converter; and, the DC-DC converter is configured to generate charging and discharging excitation currents for a power battery testing;
wherein, a high frequency in the high-frequency isolation three-level LLC resonant converter is defined as not less than 20 KHz.

As an implementation mode, the high-frequency isolation three-level LLC resonant converter is configured to be in a multi-channel parallel connection form.

A second aspect of the present invention provides a method for controlling a topology for bi-directional power conversion of an excitation power supply for power battery testing as described above, comprising:
stabilizing a voltage and balancing a power of a busbar of a high-frequency isolation three-level LLC resonant converter through a dual-loop control strategy based on voltage-loop and current-sharing loop; and
controlling, by a dual-current-loop control strategy, a duty cycle of a three-level half-bridge of a DC-DC converter, to quickly and accurately respond to charging and discharging currents.

As an implementation mode, the dual-current-loop control comprises an inductor-current inner-loop control and an output-current outer-loop control, respectively.

As an implementation mode, sampling voltages of a secondary busbar, differencing the sampled voltages from a reference voltage and using the differences as an input of the voltage-loop of the high-frequency isolation three-level LLC resonant converter; and selecting and outputting phase shift angles of primary and secondary sides or a duty ratio of a switching transistor outside the secondary side of the high-frequency isolation three-level LLC resonant converter according to different modes of the high-frequency isolation three-level LLC resonant converter.

As an implementation mode, sampling output currents of the high-frequency isolation three-level LLC resonant converter and taking an average value of the sampled output currents; differencing a current of each of channels of the high-frequency isolation three-level LLC resonant converter from the average value and using the differences as an input of the current-sharing loop to output a duty ratio of the primary side of the high-frequency isolation three-level LLC resonant converter.

As an implementation mode, an input voltage of a resonant cavity is adjusted in a forward operating state.

As an implementation mode, in a reverse operating state, adjusting a conduction time of a lower transistor of bridge arm at a rectifier side of the high-frequency isolation three-level LLC resonant converter.

As an implementation mode, when the high-frequency isolation three-level LLC resonant converter works in the forward operating state, a half-cycle operation process of the high-frequency isolation three-level LLC resonant converter is divided into six operation modes; when the high-frequency isolation three-level LLC resonant converter works in the reverse operating state, the high-frequency isolation three-level LLC resonant converter has three modes relating to energy transfer.

A third aspect of the present invention provides a system for controlling a topology for bi-directional power conversion of an excitation power supply for power battery testing, comprising a controller having a computer program stored thereon; wherein, when computer program is executed by a processor, causing the processor to implement steps of a method for controlling a topology for bi-directional power conversion of an excitation power supply for power battery testing as described above.

Compared with the prior art, the present invention has the advantages that:
(1) According to the present invention, compared with the traditional power frequency transformer and two-stage topology, the system power density by adopting new devices, new topologies and new controls is improved, reduces the volume and weight of the system; especially the switching frequency may be increased from several kHz to dozens of kHz, greatly improves the dynamic response speed of the system, the charge-discharge conversion time is short (up to millisecond level), and the test accuracy is high.
(2) According to the present invention, the current-sharing control method and the double closed-loop control strategy have simple implementation process, dynamic response speed is high and no overshoot, and can be popularized and applied to fields such as multi-phase parallel connection, etc., and can realize flexible controllable and adjustment of power level.

Additional aspects of the present invention will be set forth in part in the description which follows, and in part will be obvious from the description, or may be learned by practice of the present invention.

### BRIEF DESCRIPTION OF THE DRAWINGS

The accompanying drawings constituting a part of the present invention are used to provide a further understanding of the present invention. The exemplary examples of the present invention and descriptions thereof are used to explain the present invention, and do not constitute an improper limitation of the present invention.

FIG. 1 is a structural diagram of a three-stage power conversion topology according to an example of the present invention.

FIG. 2 is a topology diagram of a three-level LLC resonant converter according to an example of the present invention.

FIG. 3 is a critical waveform of the three-level LLC resonant converter operates in a forward direction according to an example of the present invention.

FIG. 4A is an equivalent circuit of mode 1 of the three-level LLC resonant converter operates in the forward direction according to an example of the present invention.

FIG. 4B is an equivalent circuit of mode 2 of the three-level LLC resonant converter operates in the forward direction according to an example of the present invention.

FIG. 4C is an equivalent circuit of mode 3 of the three-level LLC resonant converter operates in the forward direction according to an example of the present invention.

FIG. 4D is an equivalent circuit of mode 4 of the three-level LLC resonant converter operates in the forward direction according to an example of the present invention.

FIG. 4E is an equivalent circuit of mode 5 of the three-level LLC resonant converter operates in the forward direction according to an example of the present invention.

FIG. 4F is an equivalent circuit of mode 6 of the three-level LLC resonant converter operates in the forward direction according to an example of the present invention.

FIG. 5 is a critical waveform of the three-level LLC resonant converter operates in a reverse direction according to an example of the present invention.

FIG. 6A is an equivalent circuit of mode 1 of the three-level LLC resonant converter operates in the reverse direction according to an example of the present invention.

FIG. 6B is an equivalent circuit of mode 2 of the three-level LLC resonant converter operates in the reverse direction according to an example of the present invention.

FIG. 6C is an equivalent circuit of mode 3 of the three-level LLC resonant converter operates in the reverse direction according to an example of the present invention.

FIG. 7 is a topology diagram of a three-level DC-DC converter according to an example of the present invention.

FIG. 8 is a critical waveform for D>0.5 of the three-level DC-DC converter according to an example of the present invention.

FIG. 9 is a critical waveform for D<0.5 of the three-level DC-DC converter according to an example of the present invention.

FIG. 10A is an equivalent circuit of operation mode 1 of the three-level DC-DC converter according to an example of the present invention.

FIG. 10B is an equivalent circuit of operation mode 2 of the three-level DC-DC converter according to an example of the present invention.

FIG. 10C is an equivalent circuit of operation mode 3 of the three-level DC-DC converter according to an example of the present invention.

FIG. 10D is an equivalent circuit of operation mode 4 of the three-level DC-DC converter according to an example of the present invention.

FIG. 11 is a block diagram of a control system of the three-stage power conversion topology according to an example of the present invention.

FIG. 12 is a diagram of simulation results of charging current variation of a three-stage power conversion topology by Simulink according to an example of the present invention.

FIG. 13 is a diagram of simulation results of charging-to-discharging of the three-stage power conversion topology by Simulink according to an example of the present invention.

FIG. 14 is a diagram of simulation results of output currents of two-channel three-level LLC resonant converters in charging process of the three-level power conversion topology by Simulink according to an example of the present invention.

### DETAILED DESCRIPTION

The present invention will now be further described with reference to the accompanying drawings and examples.

It should be pointed out that the following detailed descriptions are all illustrative and are intended to provide further descriptions of the present invention. Unless otherwise specified, all technical and scientific terms used in the present invention have the same meanings as those usually understood by a person of ordinary skill in the art to which the present invention belongs.

It should be noted that the terms used herein are merely used for describing specific implementations, and are not intended to limit exemplary implementations of the present invention. As used herein, the singular form is also intended to include the plural form unless the context clearly dictates otherwise. In addition, it should further be understood that, terms “comprise” and/or “comprising” used in this specification indicate that there are features, steps, operations, devices, components, and/or combinations thereof.

### Example 1

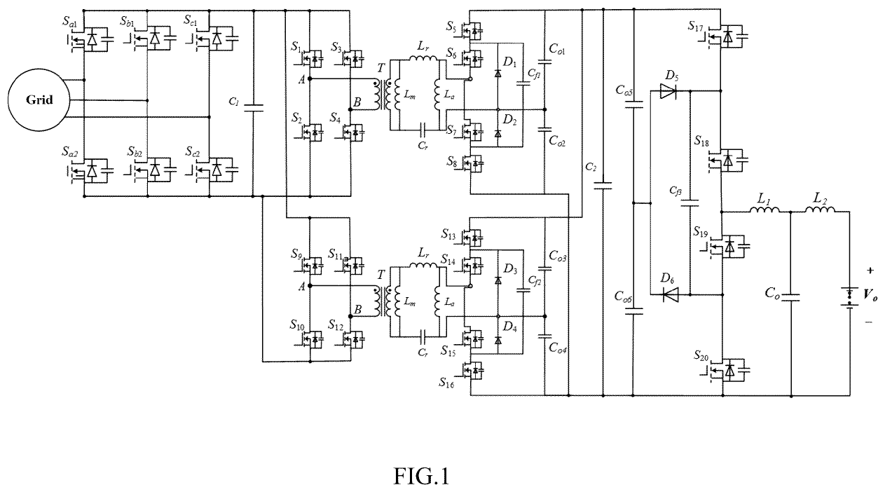

As shown in FIG. 1, the present example provides a topology for bi-directional power conversion of an excitation power supply for power battery testing, comprising:
a three-phase PWM converter, a high-frequency isolation three-level LLC resonant converter and a DC-DC converter forming a topology structure for a three-stage power conversion; wherein,
an input end of the three-phase PWM converter is connected to a power grid side; the high-frequency isolation three-level LLC resonant converter is connected between the three-phase PWM converter and the DC-DC converter in series and is configured for realizing bi-directional DC voltage conversion and isolation, and to raise a busbar voltage between the high-frequency isolation three-level LLC resonant converter and the DC-DC converter; and, the DC-DC converter is configured to generate charging and discharging excitation currents for a power battery testing;

In the present example, raising a voltage of a secondary busbar by using three-level characteristics; wherein a busbar between an AC-DC rectification and the high-frequency isolation three-level LLC resonant converter is a primary bus, and a busbar between the high-frequency isolation three-level LLC resonant converter and the DC-DC converter is the secondary busbar; the primary and secondary busbars are distinguished by primary and secondary stages of transformers.

A main function of the three-phase PWM converter is to interact with grid friendly and green, realizing low harmonics and unity power factor, and provide stable DC busbar voltage for post-stage DC-DC; a function of the high-frequency isolation three-level LLC resonant converter is mainly to convert and isolate bi-directional DC voltages, and raise the voltage of the secondary busbar by using the three-level characteristics; a main function of the DC-DC converter at the third stage is to complete a wide range, fast response, high precision charge and discharge control of an excitation current.

In the present example, the high-frequency isolation three-level LLC resonant converter is configured to be in a multi-channel parallel connection form.

### Example 2

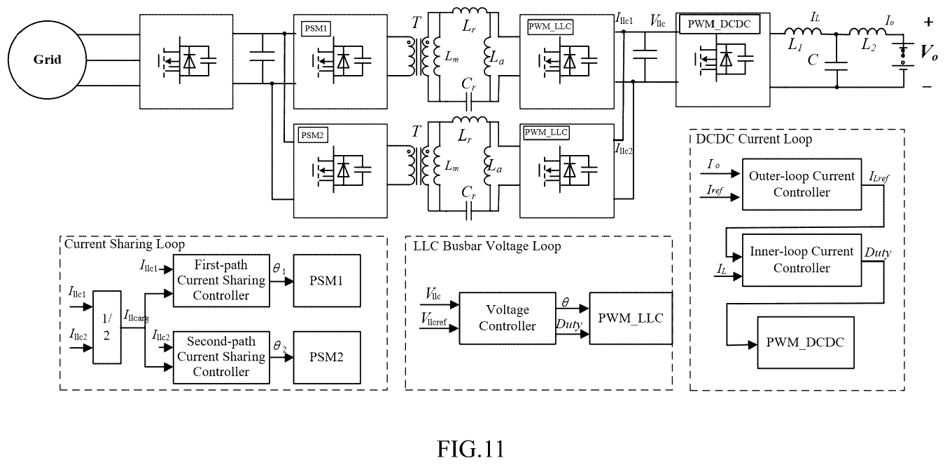

As shown in FIG. 11, the present example provides a method for controlling a topology for bi-directional power conversion of an excitation power supply for power battery testing as described above, comprising:
stabilizing a voltage and balancing a power of a busbar of a high-frequency isolation three-level LLC resonant converter through a voltage-loop and current-sharing-loop-based dual-loop control; and
outputting a duty cycle of a three-level half-bridge by a dual-current-loop control-based DC-DC converter, to quickly and accurately respond to charging and discharging currents; wherein, the dual-current-loop control comprises an inductor-current inner-loop control and an output-current outer-loop control, respectively.

In the specific implementation process, sampling voltages of a secondary busbar, differencing the sampled voltages from a reference voltage and using the differences as an input of the voltage-loop of the high-frequency isolation three-level LLC resonant converter; and selecting and outputting phase shift angles of primary and secondary sides or a duty ratio of a switching transistor outside the secondary side of the high-frequency isolation three-level LLC resonant converter according to different modes of the high-frequency isolation three-level LLC resonant converter. Sampling currents output from the high-frequency isolation three-level LLC resonant converter and taking an average value of the sampled output currents; differencing a current of each of channels of the high-frequency isolation three-level LLC resonant converter from the average value and using the differences as an input of the current-sharing loop to output the duty ratio of the primary side of the high-frequency isolation three-level LLC resonant converter. In a forward operating state, an input voltage of a resonant cavity is adjusted. In a reverse operating state, a conduction time of a lower transistor of bridge arm at a rectifier side of the high-frequency isolation three-level LLC resonant converter is adjusted.

Wherein, when the high-frequency isolation three-level LLC resonant converter works in the forward operating state, a half-cycle operation process of the high-frequency isolation three-level LLC resonant converter is divided into six operation modes; when the high-frequency isolation three-level LLC resonant converter works in the reverse operating state, the high-frequency isolation three-level LLC resonant converter has three modes relating to energy transfer.

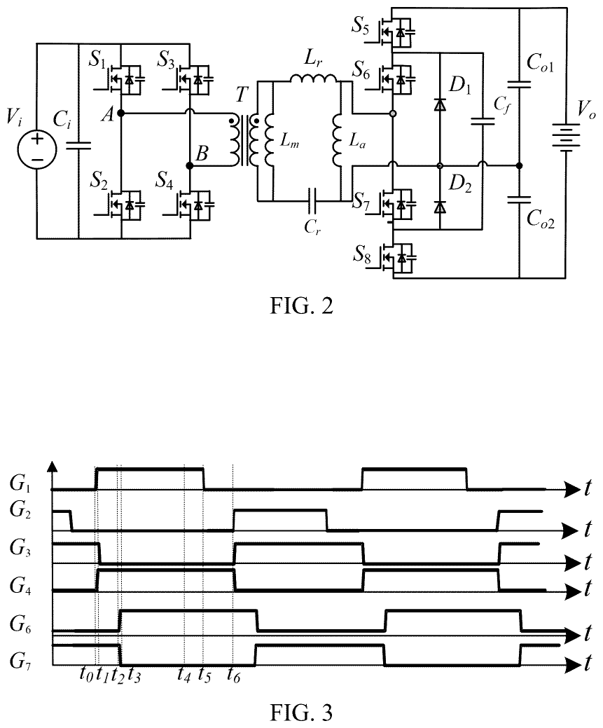

Specifically, the topology of the three-level LLC resonant converter is shown in FIG. 2, in which silicon carbide devices can be used as power switching devices to increase switching frequency and reduce volume of transformer, but the maximum power limit caused by electromagnetic losses should be comprehensively considered to design reasonable switching rate and power level. Compared with the two-level, the diode clamping type three-level increases two switch transistors and two diodes respectively, and reduces a voltage stress of the switch transistors by half. In this topology, switch transistors S₁-S₄ constitute a primary side full bridge, switch transistors S₅-S₈ and diodes D₁ and D₂ constitute a diode-clamped three-level half bridge. Lᵣ is resonant inductance, Cᵣ is resonant capacitance, T is high-frequency transformer with transformation ratio n, Lₘ is excitation inductance of transformer, and Lₐ is auxiliary inductance of transformer. The key waveforms and operating modes of the converter under different operating modes will be analyzed in detail below.

### Forward Operating Mode

The critical operating waveforms of the three-level LLC resonant converter operating in forward direction are shown in FIG. 3. As shown in FIG. 3, the primary-side switch transistor S_{3/4} of the three-level LLC resonant converter is turned on complementarily, and works together with the secondary-side switch transistors S₆ and S₇ at a fixed switching frequency, and the duty cycle is fixed at 0.5. The primary-side switch transistor S_{1/2} is turned on or off in corresponding periods, and the duty ratio is adjusted to control the input voltage of the resonant cavity, thereby improving the power sharing effect of the two channels; and the secondary-side switch transistors S₅ and S₈ work in a synchronous rectification state. However, an opening time of S₆ is delayed by an angle β relative to an opening time of S_{1/4}, and the angle β is defined as a positive boost phase shift angle, corresponding to the period [t₁, t₂] in FIG. 3.

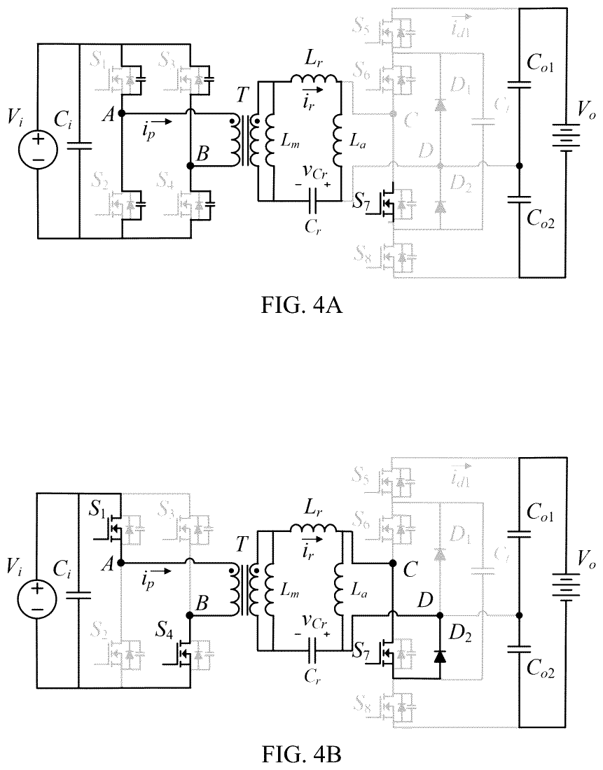

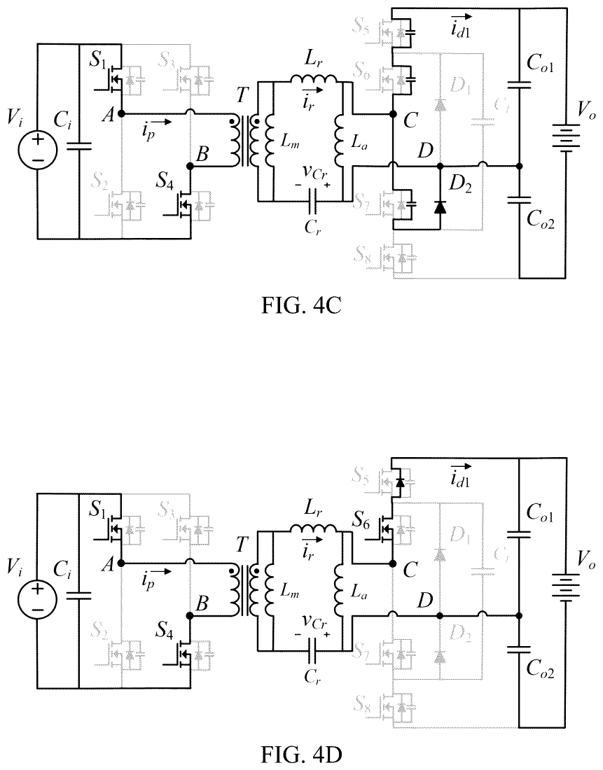

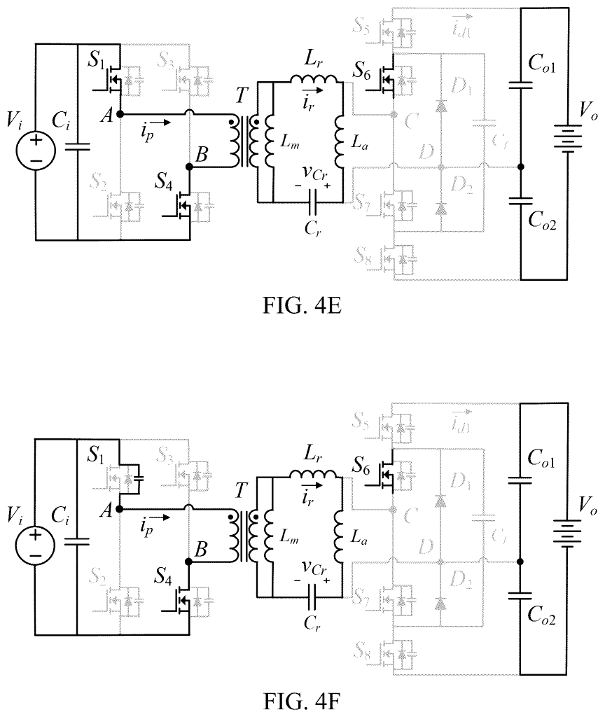

As shown in FIGS. 4A-4F, the half-cycle operation process of the three-level LLC resonant converter can be divided into six operating modes during forward boost operation, and the corresponding equivalent circuit is shown in FIG. 4. Details are as follows:

Mode 1 [t₀, t₁] [FIG. 4A]: at the moment t₀, the switch transistor S₃ is turned off and S₄ is turned on. Under an action of an excitation inductor current, a capacitance of drain-source junction of S₃ rapidly discharges to near zero, and a body diode of S₃ enters a conducting state. In this mode, the secondary switch transistor S₇ is still in a conductive state.

Mode 2 [t₁, t₂] [FIG. 4B]: starting from the moment t₁, the switch transistor S₄ realizes a zero-voltage turn-on, and the voltage ν_{AB} at an input port of the resonant cavity changes to Vᵢ/n. Under a combined action of voltages Vᵢ/n and v_{Cr}, the current i_{Lr} increases rapidly, and a direction of the current is the same as a reference direction. At this time, the secondary-side switch transistors S₇ and D₂ are conductive, an output port of the resonant cavity is short-circuited, and v_{CD} becomes zero. This mode is energy storage process of the resonant cavity, wherein the energy is input from the DC busbar, but not transmitted to load.

Mode 3 [t₂, t₃] [FIG. 4C]: this mode describes a turn-off operation of switch transistor S₇. At the moment t₂, the switch transistor S₇ is turned off, and a capacitance of drain-source junction of S₇ is gradually charged until D₂ enters a cutoff state. Capacitances of drain source junction of the switch transistors S₅ and S₆ are rapidly discharged to zero under the action of the resonant current i_{Lr}, body diodes of the switch transistors S₅ and S₆ enter a conducting state.

Mode 4 [t₃, t₄] [FIG. 4D]: at the moment t₃, voltages Vᵢ/n, v_{Cr} and Vₒ/2 act together on the inductance Lᵣ. If the sum of Vᵢ/n and v_{Cr} is greater than Vₒ/2, the current i_{Lr} changes from increasing to decreasing. Otherwise, i_{Lr} will continue to increase until Vᵢ/n and v_{Cr} are both equal to Vₒ/2, and reach a peak and then decrease. The voltage v_{Cr} gradually decreases in amplitude to zero, and then a polarity thereof changes from positive to negative and the amplitude increases. In this process, the DC busbar and the resonant cavity jointly transmit the energy to load side.

Mode 5 [t₄, t₅] [FIG. 4E]: at the moment t₄, i_{Lr} decreases to the same current as a value of a current in the inductance Lᵣ, the body diode of S₅ enters a cutoff state, S₆ still conducts, but no energy is transferred to the load side. Lᵣ resonates with the junction capacitance of the secondary-side switch transistors, resulting in slight fluctuations in the voltage v_{CD}.

Mode 6 [t₅, t₆] [FIG. 4F]: at the moment t₅, S₁ is turned off, DC busbar no longer inputs energy to the resonant cavity, S₆ still conducts, but no energy is transmitted to the load side. At this point, under the forward boost mode of the three-level LLC resonant converter, the half-switching cycle operation process is over.

Defining the boost phase shift angle β=ωᵣ(t₂−t₁), a gain function thereof for forward operation is:

$${G}_{1} = \frac{2 [ 1 + \sqrt{1 + 2 {( sin β )}^{2} / π Q} ]}{1 + cos β} ,$$

where, Q is the quality factor, and ωᵣ is the angular frequency.

### Reverse Operating Mode

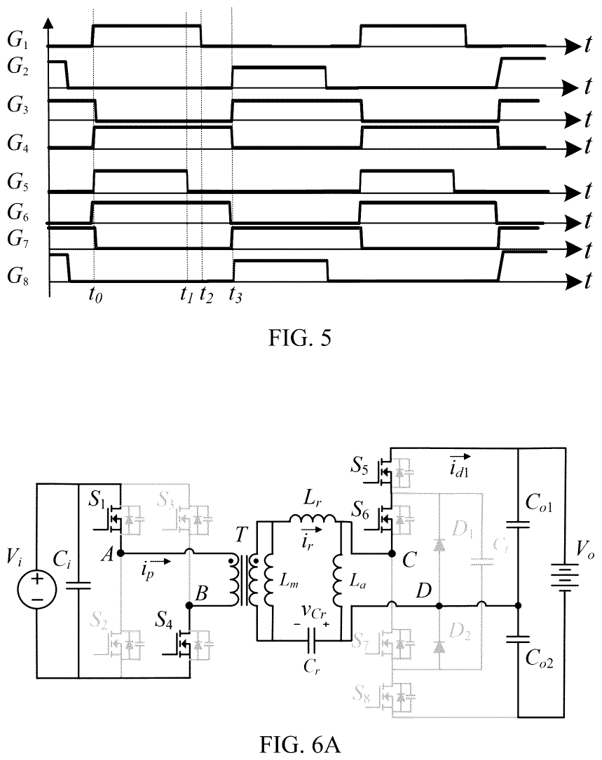

When the three-level LLC resonant converter works in reverse direction mode, the three-level half-bridge performs an inverter function and the full-bridge performs a rectifier function. FIG. 5 shows the critical waveforms for operating in the reverse direction mode, where the secondary-side switch transistors S₅-S₆ operate in PWM mode and the primary-side switch transistors S₁-S₄ operate in synchronous rectification state. Wherein, the switching transistors S₆ and S₇ conduct complementarily, the switching frequencies thereof are fixed, and the duty cycle is 0.5. The switching transistors S₅ and S₆ are turned on simultaneously, but turned off in advance: the switching transistors S₇ and S₈ are turned on simultaneously, but also turned off in advance. The input voltage of the resonant cavity is adjusted by adjusting the time when the outer transistors of the three-level bridge arm are turned on.

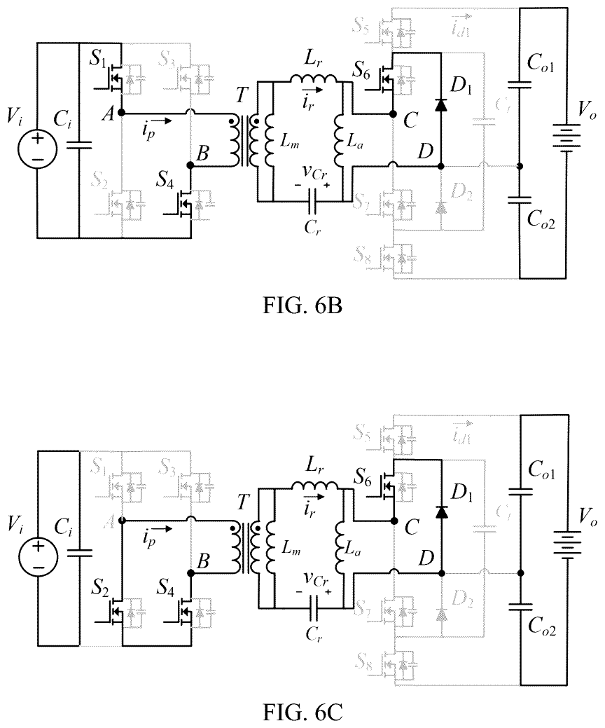

During reverse buck operation, the three-level LLC resonant converter has three main modes related to energy transfer, and the corresponding equivalent circuits are shown in FIGS. 6A-6C. Details are as follows:

Mode 1 [t₀, t₁] [FIG. 6A]: this mode describes a process of load reverse energy feed. The switch transistors S₅ and S₆ are conducting. Under the action of the voltage Vₒ/2, the energy is fed back to the input-side DC busbar through the switch transistors S₁ and S₄. The amplitude of the resonant current gradually increases and the direction of the resonant current is opposite to the reference direction. The terminal voltage v_{Cr} of the resonant capacitor decreases gradually.

Mode 2 [t₁, t₂] [FIG. 6B]: this mode describes the reverse energy feed process of the resonant capacitor. At the moment t₂, the switch transistor S₅ is turned off and the diode D₁ freewheels. The current i_{Lr} decreases rapidly. The load no longer feeds energy into the resonant cavity, and the stored energy in the resonant cavity continues to feed back to the DC busbar.

Mode 3 [t₂, t₃] [FIG. 6C]: at the moment t₃, the switch transistor S₁ is turned off and no energy is fed to the DC busbar.

Define the duty cycle D=(t₁−t₀)/(t₃−t₀) for the reverse operating mode, and then a gain function for the reverse operation is:

$${G}_{2} = \frac{- 1 + cos ( π D ) + \sqrt{{( 1 - cos ( π D ) )}^{2} - 2 π {Q ( sin ( π D ) )}^{2}}}{2 [ π Q ( 1 - cos ( π D ) ) ]} ,$$

where, Q is the quality factor.

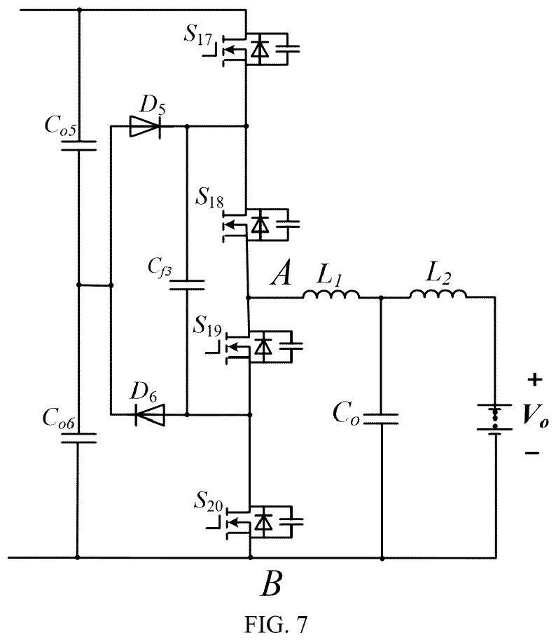

In the present example, the structure of the three-level DC-DC converter is shown in FIG. 7, and an analysis of a working principle of the three-level DC-DC converter is as follows:

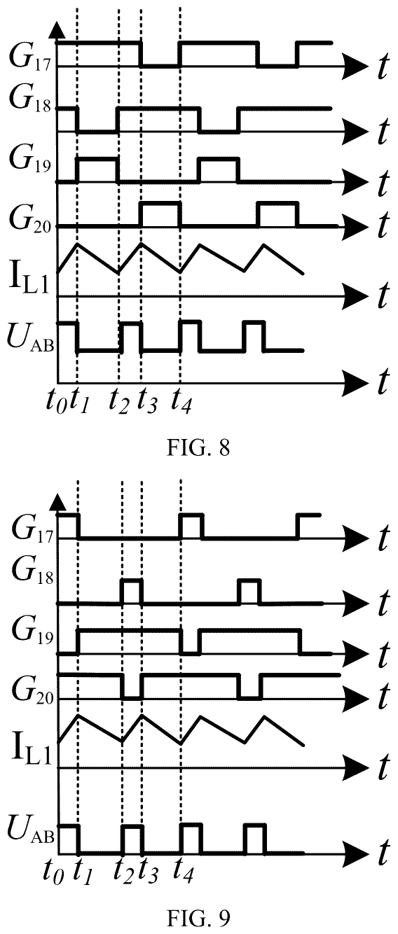

the three-level DC-DC converter works in a Buck state. When D>0.5, a driving waveform is shown in FIG. 8, U_{AB} changes between U_{H} and U_{H}/2, where a detail is as follows:

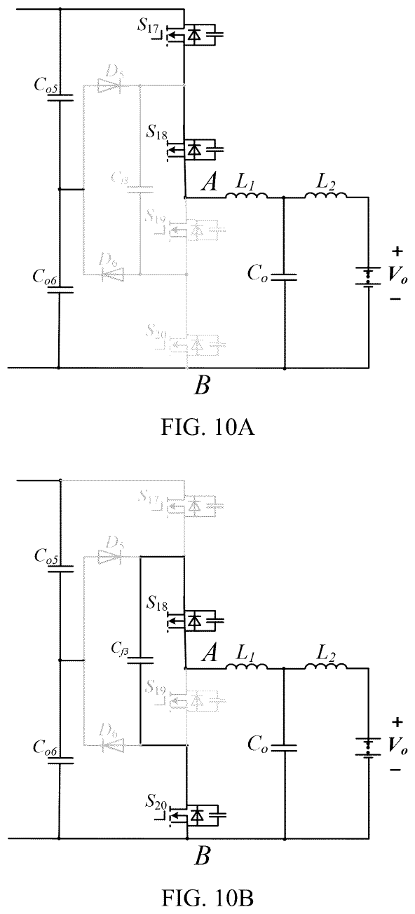

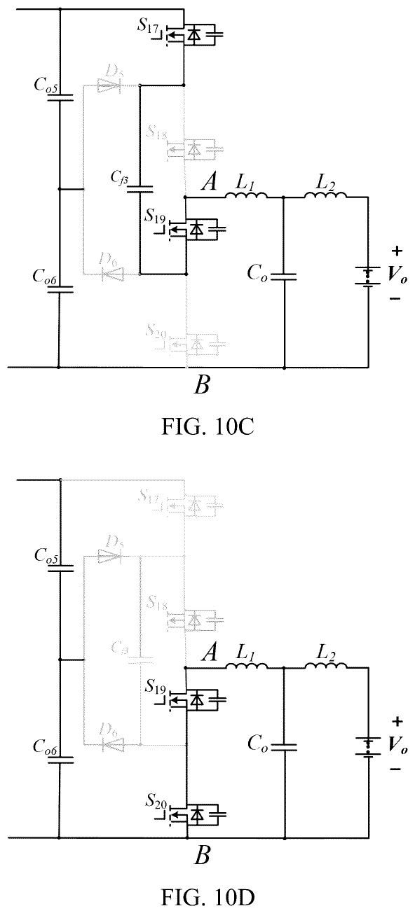

Mode 1 [t₀, t₁] [FIG. 10A]: switch transistors S₁₇ and S₁₈ are conductive. An inductor current is increased, U_{AB}=U_{H}.

Mode 2 [t₁, t₂] [FIG. 10B]: switch transistors S₁₇ and S₁₉ are conductive. The inductor current is decreased, U_{AB} =U_{H}/2.

Mode 3 [t₂, t₃] [FIG. 10C]: switch transistors S₁₇ and S₁₈ are conductive. The inductor current is increased, U_{AB} =UH.

Mode 4 [t₃, t₄] [FIG. 10D]: switch transistors S₁₈ and S₂₀ are conducting. The inductor current is decreased, U_{AB}=U_{H}/2.

Thus, a frequency of the current on a chopper inductor L1 is twice the switching frequency, and an equation of an output voltage of the three-level DC-DC converter is:

$$\begin{matrix}{U}_{O} = \frac{1}{T} {\int }_{{t}_{0}}^{{t}_{4}} {U}_{AB} dt \\ = \frac{1}{T} {\int }_{{t}_{0}}^{{t}_{4}} \{ {U}_{H} [ ( {t}_{1} - {t}_{0} ) + ( {t}_{3} - {t}_{2} ) ] + \frac{{U}_{H}}{2} [ ( {t}_{2} - {t}_{1} ) + ( {t}_{4} - {t}_{3} ) ] \} dt , \\ = {DU}_{H}\end{matrix}$$

where, Uₒ is the output voltage, U_{AB} is the voltage between points A and B, U_{H} is the input voltage of the three-level DC-DC converter, and in the present example, it is the voltage of the secondary busbar; T is the switching period.

Similarly, when D<0.5, the driving waveform is shown in FIG. 9, and the U_{AB} changes between the U_{H}/2 and zero, and an equation of the output voltage of the three-level DC-DC converter is:

$$\begin{matrix}{U}_{O} = \frac{1}{T} {\int }_{{t}_{0}}^{{t}_{4}} {U}_{AB} dt \\ = \frac{1}{T} {\int }_{{t}_{0}}^{{t}_{4}} \{ \frac{{U}_{H}}{2} [ ( {t}_{1} - {t}_{0} ) + ( {t}_{3} - {t}_{2} ) ] \} dt \\ = {DU}_{H}\end{matrix}$$

where, Uₒ is the output voltage, U_{AB} is the voltage between points A and B, U_{H} is the input voltage of the three-level DC-DC converter, and in the present example, it is the voltage of the secondary busbar.

The simulation parameters are shown in Table 1.

TABLE 1
Simulation parameters

| AC-DC busbar voltage | 700 | V |
|---|---|---|
| DC-DC busbar voltage | 1600 | V |
| output voltage | 50 V~1500 V | |
| cell voltage | 1200 | V |
| Switching frequency fₛ | 20 | kHz |
| transformer turns ratio n | 6:7 | |
| 1^{st} resonant inductance Lᵣ_{₁} | 2.375 | μH |
| 2^{nd} resonant inductance Lᵣ_{₂} | 2.625 | μH |
| 1^{st} resonant capacitor Cᵣ_{₁} | 23.75 | μF |
| 2^{nd} resonant capacitor Cᵣ_{₂} | 26.25 | μF |
| excitation inductance | 10 | μH |

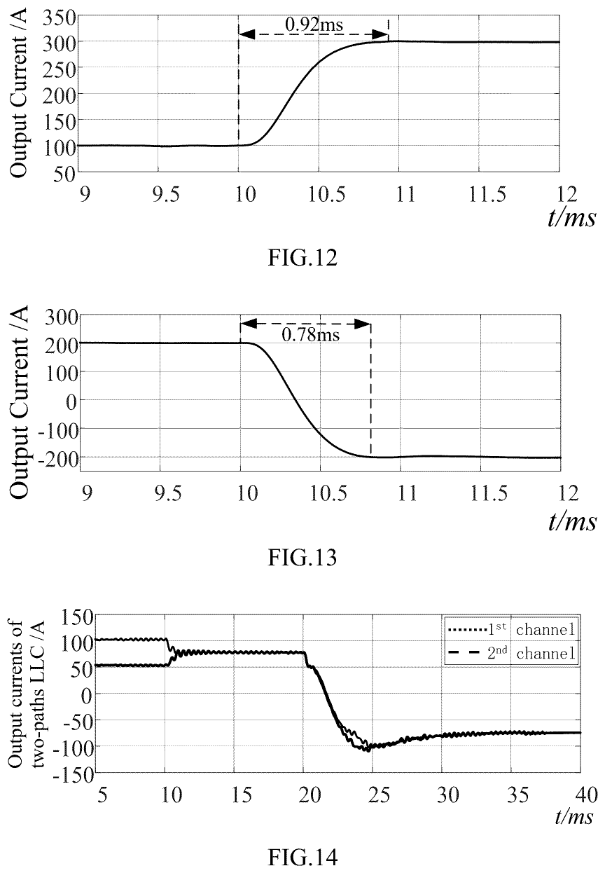

By applying the new topology of excitation power conversion and the new method for controlling voltage and current sharing of the high-frequency isolation DC-DC provided by the present invention, a change result of the charging current thereof, shown in FIG. 12, shows that it takes 0.92 ms to change from 100 A to 300 A. It can also be seen from FIG. 13 that it takes 0.78 ms to switch from charging 100 A to discharging 300 A, and there is no overshoot during the adjustment process.

As can be seen from FIG. 14, when the parameters of the resonant cavity have errors, the currents flowing through the two-channels LLC resonant converters are inconsistent, which also leads to heavy load operation of a certain phase, and the reliability of the system is reduced. After the current-sharing loop is put into operation at 10 ms, the system can achieve power balance in a very short time, and in the process of adjusting the output current, the output currents of the two-channels three-level LLC resonant converters can be kept consistent, which proves the feasibility of the current-sharing loop.

### Example 3

The present example provides a control system for a topology for bi-directional power conversion of an excitation power supply for power battery testing, comprising a controller having a computer program stored thereon; wherein, when computer program is executed by a processor, causing the processor to implement steps of a method for controlling a topology for bi-directional power conversion of an excitation power supply for power battery testing as described above.

The foregoing descriptions are merely preferred embodiments of the present invention but are not intended to limit the present invention. A person skilled in art may make various alterations and variations to the present invention. Any modification, equivalent replacement, or improvement made within the spirit and principle of the present invention shall fall within the protection scope of the present invention.

1-8. (canceled)

9. The control method for the topology for bi-directional power conversion of the excitation power supply for power battery testing according to claim 311, wherein when the high-frequency isolation three-level LLC resonant converter works in the forward operating state, a half-cycle operation process thereof is divided into six operation modes; when the high-frequency isolation three-level LLC resonant converter works in the reverse operating state, there are three modes related to energy transfer.

10. A control system for a topology for bi-directional power conversion of an excitation power supply for power battery testing, comprising a controller having a computer program stored thereon; wherein, when computer program is executed by a processor, causing the processor to implement steps of a control method for the topology for bi-directional power conversion of the excitation power supply for power battery testing according to claim 11.

11. A control method for a topology for bi-directional power conversion of an excitation power supply for power battery testing, comprising:
a control method for three-stage power conversion topology structure comprising a three-phase pulse width modulation (PWM) converter, a high-frequency isolation three-level logical link control (LLC) resonant converter, and a direct current (DC)-direct current (DC) converter;
wherein, an input end of the three-phase PWM converter is connected to a power grid side; the high-frequency isolation three-level LLC resonant converter is connected between the three-phase PWM converter and the DC-DC converter in series and is configured for realizing bi-directional DC voltage conversion and isolation, and to raise a busbar voltage between the high-frequency isolation three-level LLC resonant converter and the DC-DC converter; a three-level half-bridge is formed by four switch transistors of a secondary side of the high-frequency isolation three-level LLC resonant converter and two diodes; wherein, the four switch transistors of the secondary side of the high-frequency isolation three-level LLC resonant converter are connected in series; the two diodes are connected in series, then are connected in parallel with middle two of the four switch transistors of the secondary side; and, the DC-DC converter is configured to generate charging and discharging excitation currents for a power battery testing;
the high-frequency isolation three-level LLC resonant converter is configured to be of a two-channel parallel connection form; a two-phase three-level LLC resonant converter is controlled through a dual-loop control strategy based on a voltage-loop and a current-sharing loop, and is configured to achieve stability of the busbar voltage and power balance; the voltage-loop is configured to sample voltages of a secondary busbar, the sampled voltages of the secondary busbar are differenced from a reference voltage, as an input of the voltage-loop of the high-frequency isolation three-level LLC resonant converter, and phase shift angles of primary and secondary sides or a duty ratio of a switching transistor outside the secondary side of the high-frequency isolation three-level LLC resonant converter are output selectively according to different modes of the high-frequency isolation three-level LLC resonant converter; sampling output currents of the high-frequency isolation three-level LLC resonant converter and taking an average value of the sampled output currents, differencing a current of each of the two channels from the average value, using the differences as an input of the current-sharing-loop to output a duty ratio of the primary side of the high-frequency isolation three-level LLC resonant converter; and
the DC-DC converter is controlled by using a dual-current-loop control strategy, and is configured to output a duty cycle of the three-level half-bridge, to achieve fast and accurate response of charging and discharging currents; the dual-current-loop control strategy comprise an inductor-current inner-loop controller and an output-current outer-loop controller; wherein, an input of the output-current outer-loop controller comprises an output current and a reference current of the topology for the bi-directional power conversion of the excitation power supply for the power battery testing, an output of the output-current outer-loop controller is a reference current of the inductance-current inner-loop controller, an input of the inductance-current inner-loop controller comprises the current and an inductor current output by the output-current outer-loop controller, and an output of the inductance-current inner-loop controller is a duty cycle; the DC-DC converter is of a structure of the three-level half-bridge, an output of the DC-DC converter is connected to a LCL filter, and the inductor current is a current of a inductor of the LCL filter close to the DC-DC converter.

12. The control method for the topology for the bi-directional power conversion of the excitation power supply for the power battery testing according to claim 11, wherein in a forward operating state, adjusting an input voltage of a resonant cavity, and in a reverse operating state, adjusting a conduction time of a lower transistor of bridge arm at a rectifier side of the three-high-frequency isolation three-level LLC resonant converter.
